(19) United States
(12) Patent Application Publication
(10) Pub. No.: US 2025/0198833 A1
(43) Pub. Date: Jun. 19, 2025

(54) TRANSFER UNIT, AND SUBSTRATE PROCESSING APPARATUS INCLUDING THE SAME

(71) Applicant: SEMES CO., LTD., Cheonan-si (KR)

(72) Inventors: Ki Sang EUM, Cheonan-si (KR); Hak Jun KIM, Asan-si (KR)

(73) Assignee: SEMES CO., LTD., Cheonan-si (KR)

(21) Appl. No.: 18/982,062

(22) Filed: Dec. 16, 2024

(30) Foreign Application Priority Data
Dec. 15, 2023 (KR) 10-2023-0183022

(51) Int. Cl. G01J 1/02; H01L 21/677; H01L 21/68

(52) U.S. Cl. CPC G01J 1/02; H01L 21/67742; H01L 21/681; G01J 2001/0276

(57) ABSTRACT

Disclosed is an apparatus of processing a substrate, and more particularly, is a transfer unit for preventing contamination of a position sensor installed in a hand and a substrate processing apparatus including the same, which may prevent contamination of a position sensor that measures an alignment state of a substrate. the apparatus comprising: a chamber for providing a processing space in which a substrate is processed; and a transfer unit for loading and unloading the substrate into and from the chamber, wherein the transfer unit includes: a hand on which the substrate is placed; and a position detection assembly for measuring a position of the substrate placed on the hand, and the position detection assembly includes: an optical sensor for emitting or receiving the light; a transmitting member positioned in a path of the light between the substrate placed on the hand and the optical sensor to transmit light; and a gas supply unit for providing a gas curtain by injecting gas to a first side surface that may be the path side of the light from the transmitting member toward the substrate.

According to the exemplary embodiment of the present invention, which may prevent contamination of a position sensor that measures an alignment state of a substrate.

### CROSS-REFERENCE TO RELATED APPLICATIONS

This application claims priority to and the benefit of Korean Patent Application No. 10-2023-0183022 filed in the Korean Intellectual Property Office on Dec. 15, 2023, the entire contents of which are incorporated herein by reference.

### TECHNICAL FIELD

The present invention relates to a substrate processing apparatus, and more particularly, to a substrate processing apparatus that prevents contamination of a position sensor installed in a hand.

### BACKGROUND ART

In order to manufacture a semiconductor device, various processes, such as deposition, photography, etching, and cleaning, are performed. An apparatus performing some of these processes has a plurality of chambers. A substrate is transferred to another chamber after the process is performed in one chamber.

The substrate is transferred by a transfer robot provided in the transfer chamber. The transfer robot is provided with a hand to support the substrate while transferring the substrate. In addition, the hand is provided with a position sensor for measuring a position of the substrate in order to prevent process defects due to misalignment of the substrate.

Impurities, such as fumes and particles, are generated in the substrate on which various processes are performed. These impurities may accumulate in the position sensor while transferring the substrate. When impurities accumulate in the position sensor, there is a problem that the position of the substrate cannot be properly measured.

### SUMMARY OF THE INVENTION

The present invention has been made in an effort to provide a substrate processing apparatus capable of preventing contamination of a position sensor that measures an alignment state of a substrate.

The present invention has also been made in an effort to provide a substrate processing apparatus capable of preventing a decrease in accuracy and sensitivity for measuring an alignment state of a substrate.

The present invention has also been made in an effort to provide a substrate processing apparatus capable of increasing productivity by increasing a maintenance cycle of a transfer unit.

The problem to be solved by the present invention is not limited to the above-mentioned problems, and the problems not mentioned will be clearly understood by those skilled in the art from the descriptions below.

An exemplary embodiment of the present invention provides the apparatus comprising: a chamber for providing a processing space in which a substrate is processed; and a transfer unit for loading and unloading the substrate into and from the chamber, wherein the transfer unit includes: a hand on which the substrate is placed; and a position detection assembly for measuring a position of the substrate placed on the hand, and the position detection assembly includes: an optical sensor for emitting or receiving the light; a transmitting member positioned in a path of the light between the substrate placed on the hand and the optical sensor to transmit light; and a gas supply unit for providing a gas curtain by injecting gas to a first side surface that is the path side of the light from the transmitting member toward the substrate.

According to the exemplary embodiment of the present invention, the position detection assembly further include a cover positioned on the first side surface of the transmitting member and formed with a through-hole through which the light passes, and the gas curtain may be provided in the through-hole.

According to the exemplary embodiment of the present invention, the cover is formed with an inflow path through which the gas is supplied through the through-hole and an outflow path through which the gas may be discharged through the through-hole.

According to the exemplary embodiment of the present invention, the inflow path may be provided as a hole inside the cover.

According to the exemplary embodiment of the present invention, the outflow path is provided as a groove in an upper wall of the cover, and the groove may be formed on a surface opposite to a surface of the outer wall facing the transmitting member.

According to the exemplary embodiment of the present invention, the gas supply unit includes a gas supply line coupled to the inflow path, and the inflow path may be formed in a shape extending in a straight line from the gas supply line.

According to the exemplary embodiment of the present invention, the inflow path and the outflow path may be provided in a straight line.

According to the exemplary embodiment of the present invention, the inflow path and the outflow path may be formed parallel to the substrate supported by the hand; the optical sensor may include: a light emitting unit for emitting light; and a light receiving unit disposed opposite to the light emitting unit on a side opposite to the light emitting unit with respect to the substrate placed on the hand, and the cover is installed on at least one of the light emitting unit and the light receiving unit, and the transfer unit includes: a base; a support fixed to the base and supporting the light receiving unit; and a hand for supporting the substrate, and the hand is installed on the base and may be provided to be movable relative to the base in forward and backward directions.

According to the exemplary embodiment of the present invention, a plurality of the light emitting units and a plurality of the light receiving units are provided, one of the light emitting units and one of the light receiving units are provided to detect an edge region of the substrate, the light emitting units emit light to different regions in the edge region of the substrate, and the cover and the gas supply unit may be respectively installed in the light emitting unit and the light receiving unit.

According to the exemplary embodiment of the present invention, the transmitting member may be a lens.

Another exemplary embodiment of the present invention provides a transfer unit for transferring a substrate, the transfer unit comprising: a base; a hand for supporting a substrate; a position detection assembly for detecting a position of the substrate; and a support on which the position detection assembly is installed and which is coupled to the base, the hand is installed on the base and is provided to be movable relative to the base in forward and backward directions, the position detection assembly includes: an optical sensor for emitting light or receiving the light; a transmitting member positioned in a path of the light between the substrate placed on the hand and the optical sensor to transmit light; a cover located on the first side surface of the transmitting member; and a gas supply unit for providing a gas curtain by injecting gas into the through-hole, the cover is formed with: a through-hole through which the light passes; an inflow path through which the gas is supplied through the through-hole; and an outflow path through which the gas is discharged through the through-hole, and the gas supply unit injects gas to form a gas curtain in the through-hole.

According to the exemplary embodiment of the present invention, the cover may include the inflow path through which the gas is supplied through the through-hole and the outflow path through which the gas may be discharged through the through-hole.

According to the exemplary embodiment of the present invention, the inflow path may be provided as a hole inside the cover.

According to the exemplary embodiment of the present invention, the outflow path is provided as a groove in an upper wall of the cover, and the groove may be formed on a surface opposite to a surface of the outer wall facing the transmitting member.

According to the exemplary embodiment of the present invention, the gas supply unit may include a gas supply line coupled to the inflow path, the inflow path is formed in a shape extending in a straight line from the gas supply line, and the inflow path and the outflow path may be provided in a straight line.

According to the exemplary embodiment of the present invention, the optical sensor may include: a light emitting unit installed in the base and emitting light; a light receiving unit installed in the support and disposed to face the light emitting unit on a side opposite to the light emitting unit with respect to the substrate placed on the hand, and the cover may be installed on the light emitting unit and the light receiving unit, a plurality of the light emitting units and a plurality of the light receiving units are provided, one of the light emitting units and one of the light receiving units are provided to detect an edge region of the substrate, and the light emitting units may be emit light to different regions in the edge region of the substrate.

Still another exemplary embodiment of the present invention provides an apparatus of processing a substrate, the apparatus comprising: a process chamber for providing a processing space in which a substrate is processed; and a transfer chamber for providing a transfer space for transferring the substrate to a transfer unit, wherein the transfer chamber includes: a housing providing the transfer space; and a fan installed on an upper portion of the housing and forming descending airflow by injecting outside air into the transfer space, the transfer unit includes: a base; a hand for supporting a substrate; a position detection assembly for detecting a position of the substrate; and a support on which the position detection assembly is installed and which is coupled to the base, the hand is installed on the base and is provided to be movable relative to the base in forward and backward directions, the position detection assembly includes: an optical sensor for emitting light or receiving the light; a transmitting member positioned in a path of the light between the substrate placed on the hand and the optical sensor to transmit light; a cover located on the first side surface of the transmitting member; and a gas supply unit for providing a gas curtain by injecting gas into the through-hole, the cover is formed with: a through-hole through which the light passes; an inflow path through which the gas is supplied through the through-hole, and which is provided as a hole inside the cover; and an outflow path which is provided as a groove in an upper wall of the cover and through which the gas may be discharged through the through-hole, the inflow path and the outflow path are formed in a straight line and parallel to the substrate supported by the hand, and the gas supply unit injects gas to form a gas curtain in the through-hole.

According to the exemplary embodiment of the present invention, the optical sensor may include: a light emitting unit installed in the base and emitting light; and a light receiving unit installed in the support and disposed to face the light emitting unit on a side opposite to the light emitting unit with respect to the substrate placed on the hand, and the cover is installed on the light emitting unit and the light receiving unit, a plurality of the light emitting units and a plurality of the light receiving units are provided, one of the light emitting units and one of the light receiving units are provided to detect an edge region of the substrate, and the light emitting units emit light to different regions in the edge region of the substrate.

According to the exemplary embodiment of the present invention, one of the light emitting units and one of the light receiving units are provided to detect an edge region of the substrate, and the light emitting units emit light to different regions in the edge region of the substrate.

According to the exemplary embodiment of the present invention, it is possible to prevent contamination of a position sensor that measures an alignment state of a substrate.

In addition, according to the exemplary embodiment of the present invention, it is possible to prevent a decrease in accuracy and sensitivity for measuring an alignment state of a substrate.

In addition, according to the exemplary embodiment of the present invention, it is possible to increase a maintenance cycle to improve productivity.

The effect of the present invention is not limited to the foregoing effects, and those skilled in the art may clearly understand non-mentioned effects from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram illustrating a substrate processing facility according to an exemplary embodiment of the present invention as viewed from above.

FIG. 2 is a diagram illustrating the facility of FIG. 1 as viewed from the direction A-A.

FIG. 3 is a diagram illustrating the facility of FIG. 1 as viewed from the direction B-B.

FIG. 4 is a diagram illustrating the facility of FIG. 1 as viewed from the direction C-C.

FIG. 5 is a diagram illustrating a transfer unit according to the exemplary embodiment of the present invention.

FIG. 6 is a diagram illustrating a position detection assembly according to the exemplary embodiment of the present invention.

FIG. 7 is a diagram illustrating a state in which a light emitting unit and a light receiving unit of FIG. 6 detect positions of a substrate.

FIG. 8 is a diagram illustrating an exemplary embodiment of a cover of FIG. 6.

FIG. 9 is a diagram illustrating a shape in which an inflow path, a through-hole, and an outflow path formed in the cover of FIG. 8 are connected to each other.

FIG. 10 is a diagram illustrating a state in which a gas curtain is formed in the through-hole.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate processing, in addition to wafers.

Hereinafter, exemplary embodiments of the present invention will be described with reference to the accompanying drawings.

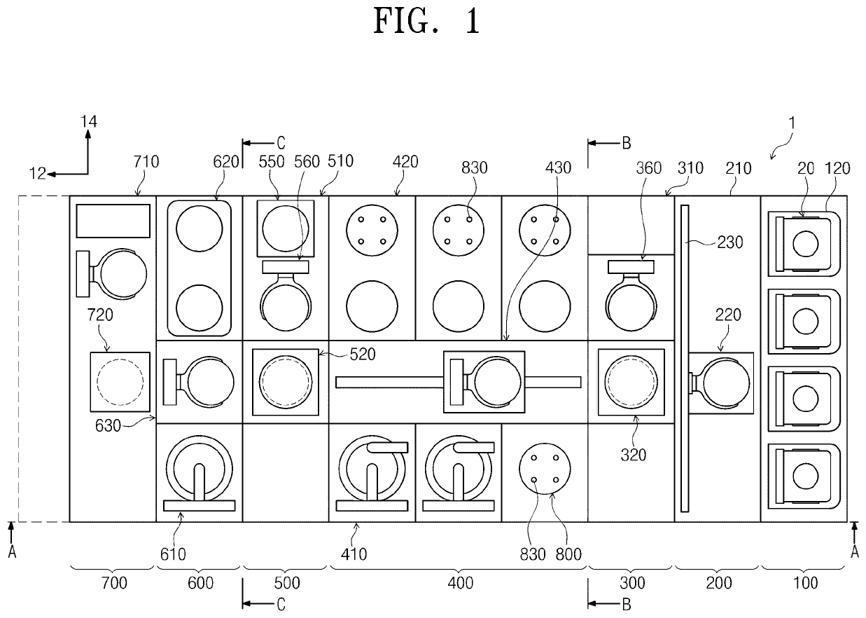

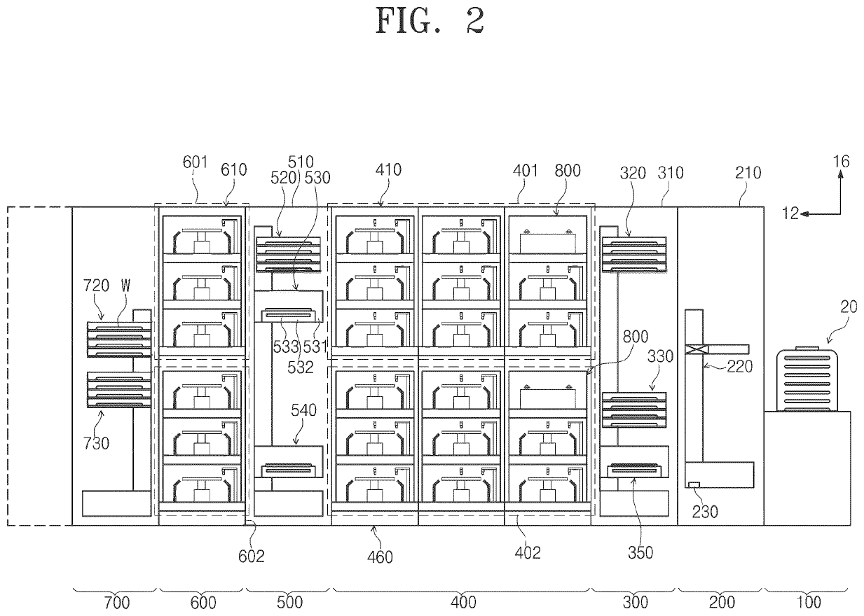

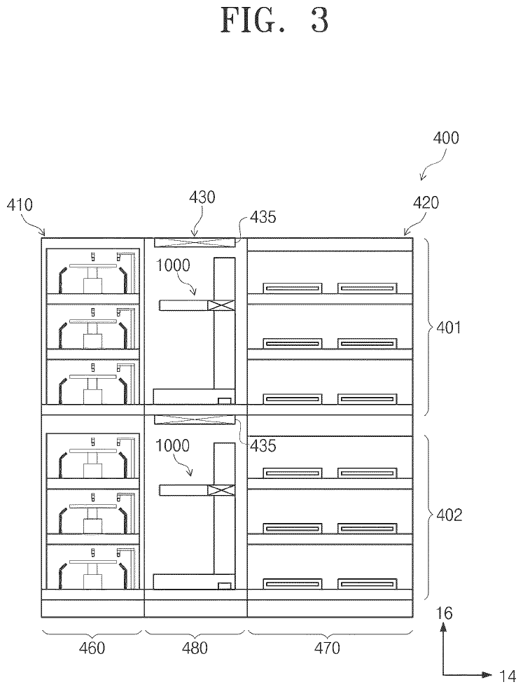

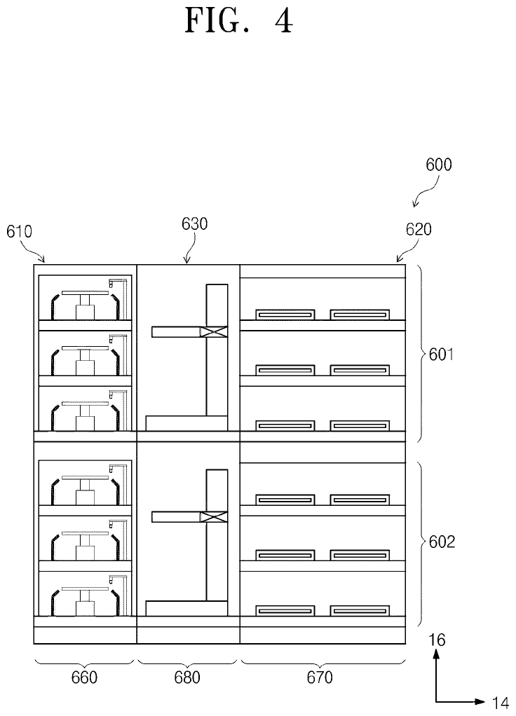

Referring to FIGS. 1 to 4, a substrate processing facility 1 includes a load port 100, an index module 200, a first buffer module 300, an applying and developing module 400, a second buffer module 500, a pre- and post-exposure processing module 600, and an interface module 700.

Hereinafter, a direction in which the load port 100, the index module 200, the first buffer module 300, the applying and developing module 400, the second buffer module 500, the pre and post-exposure processing module 600, and the interface module 700 are arranged is arranged is referred to as a first direction 12, when viewed from the top, a direction perpendicular to the first direction 12 is referred to as a second direction 14, and a direction perpendicular to the first direction 12 and the second direction 14 is referred to as a third direction 16.

A substrate W is moved while being accommodated in a cassette 20. In this case, the cassette 20 has a structure that may be sealed from the outside. For example, as the cassette 20, a Front Open Unified Pod (FOUP) having a door at the front may be used.

Hereinafter, the load port 100, the index module 200, the first buffer module 300, the applying and developing module 400, the second buffer module 500, the pre and post-exposure processing module 600, and the interface module 700 will be described in detail.

The load port 100 includes a mounting table 120 on which the cassette 20 in which the substrates W are accommodated is placed. A plurality of mounting tables 120 is provided, and the mounting tables 120 are arranged in a line in the second direction 14. In FIG. 1, four mounting tables 120 are provided.

The index module 200 transfers the substrate W between the cassette 20 placed on the mounting table 120 of the load port 100 and the first buffer module 300. The index module 200 includes a frame 210, an index robot 220, and a guide rail 230. The frame 210 is provided in the shape of a rectangular parallelepiped with an empty interior, and is disposed between the load port 100 and the first buffer module 300.

The first buffer module 300 includes the frame 310, a first buffer 320, a second buffer 330, a cooling chamber 350, and a first buffer robot 360. The frame 310 is provided in the shape of a rectangular parallelepiped with an empty interior, and is disposed between the index module 200 and the applying and developing module 400. The first buffer 320, the second buffer 330, the cooling chamber 350, and the first buffer robot 360 are positioned in the frame 310. The first buffer 320 and the second buffer 330 temporarily store the plurality of substrates W, respectively. The first buffer robot 360 transfers the substrate W between the first buffer 320 and the second buffer 330. The cooling chamber 350 cools the substrate W.

The applying and developing module 400 performs a process of applying a photoresist on the substrate W before the exposure process and a process of developing the substrate W after the exposure process. The applying and developing module 400 generally has a rectangular parallelepiped shape. The applying and developing module 400 includes an applying module 401 and a developing module 402.

The applying module 401 and the developing module 402 are arranged to be partitioned between each other in layers. According to an example, the applying module 401 is located above the developing module 402.

The applying module 401 performs a process of applying a photosensitive liquid, such as a photoresist, to the substrate W and a heat treatment process, such as heating and cooling, on the substrate W before and after the resist applying process.

The applying module 401 includes a resist applying chamber 410, a bake chamber 420, and a transfer chamber 430. The resist applying chamber 410, the bake chamber 420, and the transfer chamber 430 are sequentially disposed in the second direction 14. Accordingly, the resist applying chamber 410 and the bake chamber 420 are positioned while being spaced apart from each other in the second direction 14 with the transfer chamber 430 interposed therebetween.

A plurality of resist applying chambers 410 is provided, and a plurality of resist applying chambers are provided in each of the first direction 12 and the third direction 16. In the drawing, an example in which six resist applying chambers 410 are provided is illustrated.

The bake chamber 420 performs heat treatment on the substrate W. For example, the bake chambers 420 performs a prebake process of heating the substrate W to a predetermined temperature before coating the photoresist to remove organic matter or moisture on the surface of the substrate W or a soft bake process performed after coating the photoresist on the substrate W, and performs a cooling process of cooling the substrate W after each heating process.

The transfer chamber 430 is positioned in parallel with the first buffer 320 of the first buffer module 300 in the first direction 12. The transfer chamber 430 includes a transfer unit 1000 for transferring the substrate W, and a fan filter unit 435 which provides descending airflow to the inside of the transfer chamber 430 to provide descending airflow to the substrate. The transfer unit 1000 will be described below.

The developing module 402 performs a developing process for removing a part of the photoresist by supplying a developer to obtain a pattern on the substrate W, and a heat treatment process, such as heating and cooling, performed on the substrate W before and after the developing process. The developing module 402 includes a developing chamber 460, a bake chamber 470, and a transfer chamber 480. The developing chamber 460, the bake chamber 470, and the transfer chamber 480 are sequentially disposed along the second direction 14.

The developing chambers 460 all have the same structure. However, the types of developer used in the developing chambers 460 may be different from each other. The developing chamber 460 removes a region irradiated with light from the photoresist on the substrate W. At this time, the region irradiated with light among a passivation film is also removed. Only a region to which light is not irradiated among regions of the photoresist and the passivation layer may be removed according to the type of the selectively used photoresist.

The bake chamber 470 of the developing module 402 heats the substrate W. For example, the bake chambers 470 perform a post-bake process that heats the substrate W before the developing process is performed, a hard bake process that heats the substrate W after the developing process is performed, and a cooling process that cools the heated substrate W after each baking process.

The second buffer module 500 is provided as a passage through which the substrate W is transported between the applying and developing module 400 and the pre- and post-exposure processing module 600. Furthermore, the second buffer module 500 performs a predetermined process, such as a cooling process, an edge exposure process, or the like, on the substrate W. The second buffer module 500 has a frame 510, a buffer 520, a first cooling chamber 530, a second cooling chamber 540, an edge exposure chamber 550 and a second buffer robot 560.

When the exposure apparatus performs a liquid immersion exposure process, the pre- and post-exposure processing module 600 may perform a process of applying a protective film protecting the photoresist film applied to the substrate W during liquid immersion exposure. In addition, the pre- and post-exposure processing module 600 may perform a process of cleaning the substrate W after exposure. In addition, when the applying process is performed using a chemical amplification resist, the pre- and post-exposure processing module may perform a baking process after exposure.

The pre- and post-exposure processing module 600 includes a pre-processing module 601 and a post-processing module 602-. The pre-processing module 601 performs a process of processing the substrate W before performing the exposure process, and the post-processing module 602 performs a process of processing the substrate W after the exposure process.

In the pre- and post-exposure processing module 600, the pre-processing module 601 and the post-processing module 602 are provided to be completely separated from each other.

The pre-processing module 601 has a protective film applying chamber 610, a bake chamber 620, and a transfer chamber 630. The protective film applying chamber 610, the transfer chamber 630, and the bake chamber 620 are sequentially disposed along the second direction 14.

Therefore, the protective film applying chamber 610 and the bake chamber 620 are sequentially disposed along the second direction 14 with the transfer chamber 630 interposed therebetween. A plurality of protective film applying chambers 610 are provided and are disposed along the third direction 16 to form layers with each other.

Optionally, a plurality of protective film applying chambers 610 may be provided in each of the first direction 12 and the third direction 16. A plurality of bake chambers 620 are provided, and are disposed along the third direction 16 to form layers with each other. Optionally, a plurality of bake chambers 620 may be provided in each of the first direction 12 and the third direction 16.

The post-processing module 602 includes a cleaning chamber 660, a post-exposure bake chamber 670, and a transfer chamber 680. The cleaning chamber 660, the transfer chamber 680, and the post-exposure bake chamber 670 are sequentially disposed along the second direction 14.

Accordingly, the cleaning chamber 660 and the post-exposure bake chamber 670 are positioned to be spaced apart from each other in the second direction 14 with the transfer chamber 680 interposed therebetween. A plurality of cleaning chambers 660 may be provided and may be disposed along the third direction 16 to form a layer on each other.

Optionally, a plurality of cleaning chambers 660 may be provided in each of the first direction 12 and the third direction 16. A plurality of post-exposure bake chambers 670 may be provided, and may be disposed along the third direction 16 to form a layer on each other. Optionally, a plurality of post-exposure bake chambers 670 may be provided in each of the first direction 12 and the third direction 16.

The interface module 700 transfers the substrate W between the pre- and post-exposure processing module 600. The interface module 700 includes a frame 710, a first buffer 720, a second buffer 730, and an interface robot 740. The first buffer 720, the second buffer 730, and the interface robot 740 are positioned in the frame 710.

The first buffer 720 and the second buffer 730 are spaced apart from each other by a predetermined distance and are arranged to be stacked on each other. The first buffer 720 is disposed higher than the second buffer 730. The first buffer 720 is positioned at a height corresponding to the pre-processing module 601, and the second buffer 730 is positioned at a height corresponding to the post-processing module 602. When viewed from the top, the first buffer 720 is arranged in a line with the transfer chamber 630 of the pre-processing module 601 along the first direction 12, and the second buffer 730 is arranged in a line with the transfer chamber 630 of the post-processing module 602 along the first direction 12.

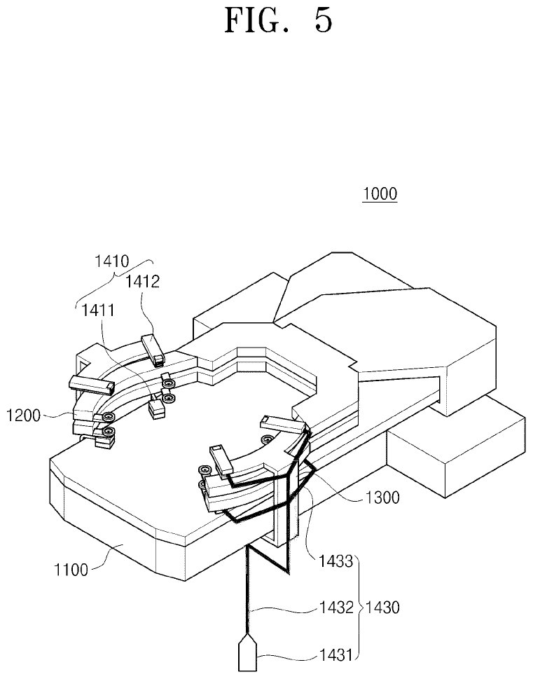

The transfer unit 1000 transfers the substrate W between the applying chamber 410 and the bake chamber 420. FIG. 5 is a diagram illustrating the transfer unit according to the exemplary embodiment of the present invention. Referring to FIG. 5, the transfer unit 1000 includes a base 1100, a hand 1200, a support 1300, and a position detection assembly 1400. The base 1100 provides a base for the transfer unit 1000. The hand 1200, the support 1300, and the position detection assembly 1400 are installed on the base 1100. The hand 1200 supports the substrate W. The hand 1200 is provided to be relatively movable in forward and backward directions with respect to the base W. Accordingly, the hand 1200 may load the substrate W into the applying chamber 410 and the bake chamber 420, or may unload the substrate W from the applying chamber 410 and the bake chamber 420. The support 1300 supports the position detection assembly 1400. The support may be installed on a side surface of the base 1100. A lower end of the support 1300 may be installed on a lower end of the base 1100. According to the example, the support 1300 may have a “ [symbol] ” shaped cross section in the third direction 16. Accordingly, the support 1300 may have a shape surrounding a portion of the side surface of the support 1300 and a portion of the hand 1200 in a backward state. The position detection assembly 1400 may be installed on an upper end of the support 1300.

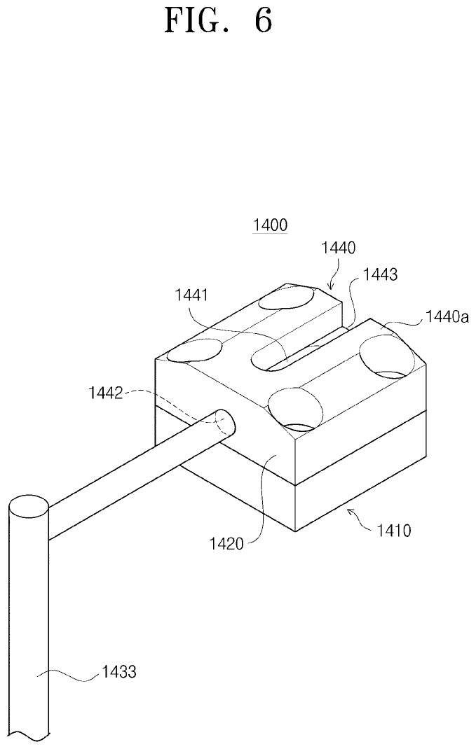

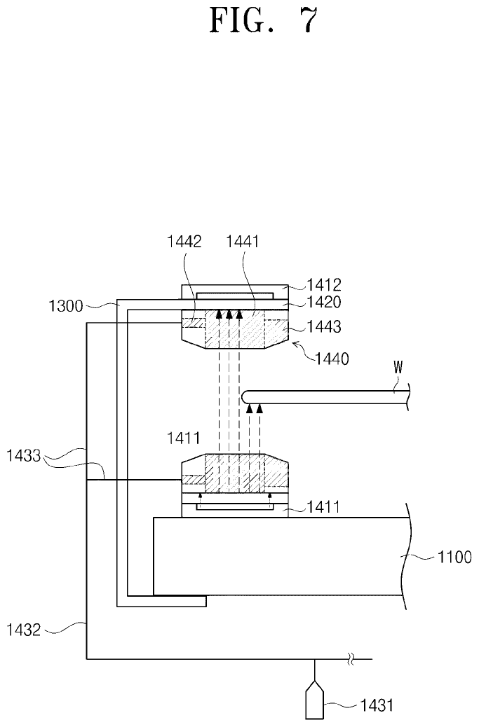

The position detection assembly 1400 measures an alignment state of the substrate W. The position detection assembly 1400 detects an alignment state of the substrate W placed on the hand 1200. FIG. 6 is a diagram illustrating the position detection assembly according to the exemplary embodiment of the present invention, and FIG. 7 is a diagram illustrating a state in which a light emitting unit and a light receiving unit of FIG. 6 detect positions of a substrate. Referring to FIGS. 6 to 7, the position detection assembly 1400 detects an end position on the substrate W held in the hand 1200. The position detection assembly 1400 emits light toward the substrate placed on the hand 1200 and measures a degree of misalignment of the substrate as an area of sensed light. A plurality of position detection assemblies 1400 may be provided. For example, four position detection assemblies 1400 may be provided at positions facing each other. In this case, the position detection assembly 1400 may detect four end positions on the substrate W. The position detection assembly 1400 includes an optical sensor 1410, a transmitting member 1420, a gas supply unit 1430, and a cover 1440.

The optical sensor 1410 detects the alignment state of the substrate W by using light. The optical sensor 1410 may emit light. Also, the optical sensor 1410 may receive light. As an example, the optical sensor 1410 may be provided as a laser displacement sensor. The optical sensor 1410 may include a light emitting unit 1411 and a light receiving unit 1412. The light emitting unit 1411 emits light. The light emitting unit 1411 includes a light source. The light source of the light emitting unit 1411 may be provided as laser light. Alternatively, the light source of the light emitting unit 1411 may be provided as LED light. The light receiving unit 1412 receives the light emitted from the light emitting unit 1411. The light receiving unit 1412 may measure the position of the substrate W according to the amount of received light. As an example, in the absence of the substrate W, the amount emitted from the light emitter 1411 is taken as a reference value. Thereafter, when light is emitted from the light emitting unit 1411 in the state where the position detection assembly is held by the hand 1200, the position of the substrate W is measured based on the received amount of light excluding the amount of light covered by the substrate W. The light receiving unit 1412 receives laser light when the optical sensor 1410 is provided in laser displacement. Alternatively, when the light emitting unit 1411 emits LED light, the light receiving unit 1412 may be provided as a linear image sensor. For example, the linear image sensor may be provided with various linear image sensors, such as a Charge Coupled Device (CCD) line sensor, a fiber line sensor, and a photoelectric sensor.

The transmitting member 1420 is disposed in a path of light. The transmission 1420 may be provided between the light emitting unit 1411 and the substrate W. The transmitting member 1420 may be provided at a position adjacent to the light emitting unit 1411. Also, the transmitting member 1420 may be provided between the light receiving unit 1412 and the substrate W. The transmitting member 1420 may be provided at a position adjacent to the light receiving unit 1412. According to the example, the light source of the light emitting unit 1411 may be installed in a first body (not illustrated) having a first opening (not illustrated), the transmitting member 1420 may be installed in the opening, and the sensor of the light receiving unit 1412 may also be installed in a second body (not illustrated) having a second opening, and the transmitting member 1420 may be installed in the second opening (not illustrated). The transmitting member 1420 may transmit light emitted from the light source of the light emitting unit 1411. When the optical sensor 1410 includes the light emitting unit 1411 and the light receiving unit 1412, the transmitting member 1420 may be provided at opposite sides between the light emitting unit 1411 and the substrate W, and between the light receiving unit 1412 and the substrate W. According to the example, the transmitting member 1420 may be a lens. The gas supply unit 1430 includes a gas supply source 1431, a main supply line 1432, and a plurality of gas supply lines 1433. The gas supply source 1431 stores and supplies gas. According to the example, the gas may be nitrogen or Clean Dry Air (CDA). The gas supply source 1431 is connected to the main supply line 1432. The main supply line 1432 branches to a plurality of gas supply lines 1433. A plurality of gas supply lines 1433 are connected to a plurality of inlets 1442a, respectively. According to the example, an inflow path 1442 may extend in a straight line from the gas supply line 1433.

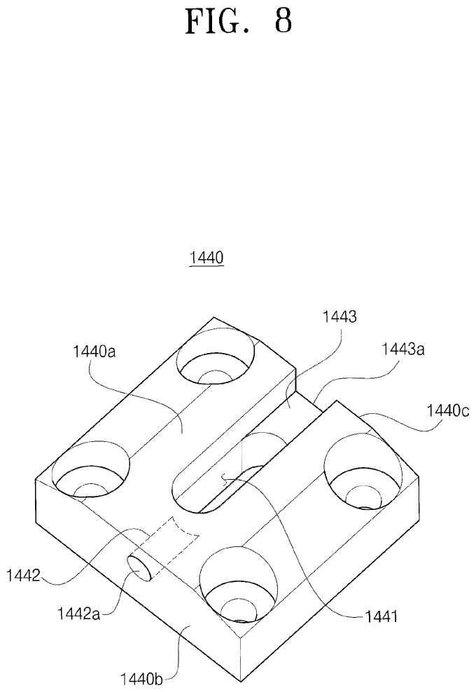

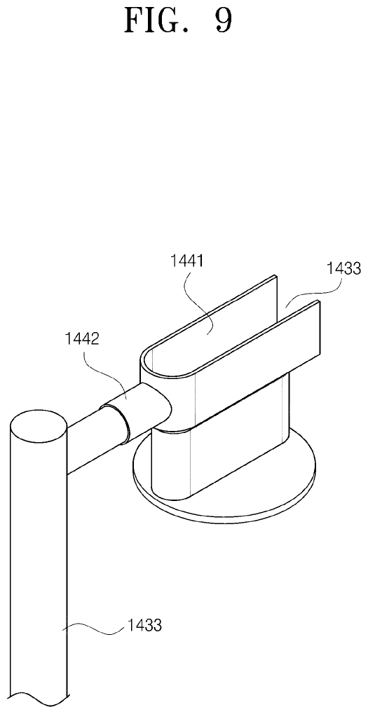

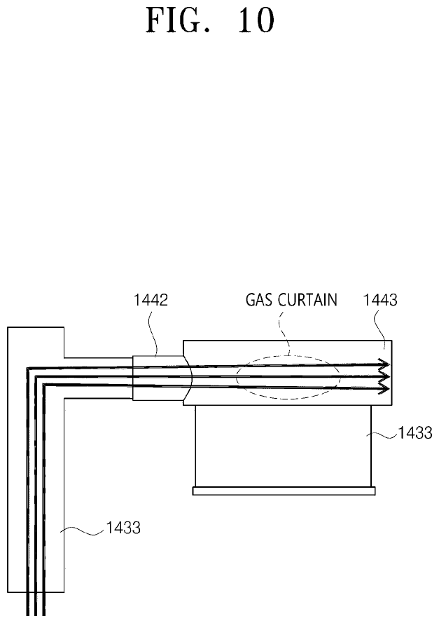

FIG. 8 is a diagram illustrating an exemplary embodiment of the cover of FIG. 6, FIG. 9 is a diagram illustrating a shape in which the inflow path, the through-hole, and an outflow path of the cover of FIG. 8 are connected to each other, and FIG. 10 is a diagram illustrating a state in which a gas curtain is formed in the through-hole. The cover 1440 may be located on a first side surface 1421 of the transmitting member 1420. The first side surface 1421 may be a surface of the transmitting member 1420 facing the substrate W. A through-hole 1441, the inflow path 1442, an outflow path 1443, and a coupling portion 1444 may be formed in the cover 1440.

The through-hole 1441 provides a path through which light emitted by the light source of the light emitting unit 1411 passes. The through-hole 1441 may be provided to vertically pass through the cover 1440. The through-hole 1441 may be provided in a shape perpendicular to the transmitting member 1420. The through-hole 1441 may be provided in a shape having one longitudinal direction. Also, the through-hole 1441 may be formed to correspond to a sensor detection range of the optical sensor 1410. The through-hole 1441 may be formed to correspond to a minimum area required for the optical sensor 1410 to detect an alignment state of the substrate W. Accordingly, even if a range in which the transmitting member 1420 may transmit light is limited by the cover 1440, the optical sensor 1410 may measure the alignment of the substrate W. According to the example, a detection range of the optical sensor 1410 may be ±4 mm (PCD 308 mm), and when viewed from above, the through-hole 1441 may have a shape including a rectangle. Gas injected by the gas supply unit 1430 which will be described later may be introduced into the inner space 1441a of the through-hole 1441. Accordingly, a gas curtain may be formed in the through-hole 1441.

The inflow path 1442 may be provided adjacent to a top surface 1440a of the cover 1440. The inflow path 1442 may be provided as a hole in an upper portion of the cover 1440. A width t of the outflow path 1443 may be provided to coincide with a width t of the through-hole 1441 in the longitudinal direction. The inflow path 1442 may be provided horizontally. The inflow path 1442 may be provided to be parallel to the substrate W supported by the hand 1200. The inflow path 1442 may be formed in a direction extending from the longitudinal direction of the through-hole 1441. An inlet port 1442 is formed in one side surface of the cover 1440. The inflow path 1442 connects the inlet port and the through-hole 1441. A gas supply unit 1430 is connected to the inflow path 1442. Accordingly, the gas injected from the gas supply unit 1430 is introduced into the through-hole 1441 through the inflow path 1442 to form a gas curtain.

The outflow path 1443 may be provided adjacent to the top surface of the cover 1440. The outflow path 1443 may be provided in a shape in which an upper portion is open. The outflow path 1443 may be provided as a groove in the top surface 1440a of the cover. The width t of the outflow path 1443 may be provided to coincide with the width t of the through-hole 1441 in the longitudinal direction. A bottom surface 1443 of the outflow path 1443 may be provided in a plane. The height of the bottom surface 1443b of the outflow path 1443 may be provided to coincide with the height of the bottom surface 1442b of the inflow path 1442. The outflow path 1443 may be provided horizontally. The outflow path 1443 may be provided to be parallel to the substrate W supported by the hand 1200. The outflow path 1443 may be formed in a direction extending from the longitudinal direction of the through-hole 1441. An outlet port is formed on the other side surface 1440c of the cover 1440. The outflow path 1443 connects the through-hole 1441 and the outlet 1443a. Accordingly, the gas introduced into the through-hole 1441 is discharged to the outside of the cover 1440 through the outflow path 1443.

The inflow path 1442, the through-hole 1441, and the outflow path 1443 are provided as paths through which gas discharged from the gas supply unit 1430 flows. The inflow path 1442, the through-hole 1441, and the outflow path 1443 may be disposed on an imaginary straight line when viewed from above. The gas may be injected into the inflow path 1442, and may form an air curtain in the through-hole 1441 while moving straight to the outflow path 1443, and the gas is discharged from the cover 1440 through the outflow path 1443. The gas is discharged in parallel with the substrate W. The direction in which the gas is discharged may be variously provided according to the structure in which the main gas supply line 1432 and the gas supply line 1433 are installed. According to the exemplary embodiment, the coupling direction of the cover 1440 may be determined such that the gas is discharged in a direction in which the gas is radiated from the substrate W, but the present invention is not limited thereto, and as long as the gas may be discharged in parallel with the substrate W, the cover 1440 may be installed in an arbitrary direction.

The coupling portion 1444 is provided to be coupled to a coupling means for coupling the transmitting member 1420 and the cover 1440. The coupling portion 1444 may be provided to penetrate upper and lower portions of the cover 1440. According to the exemplary embodiment, the coupling portion 1444 may be provided as a screw hole. A plurality of coupling portions 1444 may be provided. Furthermore, the cover 1444 may be coupled to the optical sensor 1410. The optical sensor 1410 may have a coupling portion (not illustrated) at a position corresponding to the coupling portion 1444 of the cover 1440. According to the exemplary embodiment, both of the coupling portion 1444 of the cover and the coupling portion of the optical sensor may be provided as a screw hole, and each coupling portion may be fixed by a screw hole in a state in which the coupling portion is aligned. The transmitting member 1420 may be provided between the optical sensor 1410 and the cover 1440.

According to the exemplary embodiment of the present invention, the gas supply line 1433, the inflow path 1442, the through-hole 1441, and the outflow path 1443 are provided in a straight line, thereby securing straightness of the gas injected through the gas supply line 1433. Accordingly, the gas forms an air curtain in the through-hole 1441.

A photoresist is applied on the substrate W in the resist applying chamber 410, and the substrate W is heat-treated in the bake chamber 420. The heat-treated substrate W is unloaded to the transfer chamber 430 by the transfer unit 1000. Impurities, such as fumes and particles, are discharged while the substrate W is transferred. Since descending airflow is formed by the fan filter unit 435 inside the transfer chamber 430, impurities generated from the substrate W may be directed to the transfer unit. In this case, since the gas curtain is formed in the through-hole 1441, impurities directed to the transmitting member 1420 may be blocked with the gas curtain. Accordingly, contamination of the transmitting member 1420 and the optical sensor 1410 may be prevented. Accordingly, the accuracy and sensitivity of the optical sensor 1410 may be prevented from being degraded due to contamination of the impurities. Also, the maintenance period of the transfer unit 1000 may be increased to improve productivity.

In addition, by allowing the gas to be injected parallel to the substrate W, the influence of the gas on the substrate W may be minimized. In particular, in the case of the substrate W treated at a high temperature, the substrate W is cooled while the substrate W is being transferred, and by spraying the gas parallel to the substrate W, the temperature imbalance on the substrate W may be prevented by minimizing the influence of the gas on cooling.

In the above example, the present invention has been described based on the transfer unit 1000 of the transfer chamber 430 provided to the coating module 401 as an example. However, the present invention is not limited thereto, and the transfer units 1000 may also be provided to the transfer chamber 480 of the developing module 402 and the transfer chambers 630 and 680 of the pre- and post-exposure processing module 600.

Furthermore, the present invention has been described based on the case where the transmitting member 1420 is a lens as an example. However, the present invention is not limited thereto, and the transmitting member 1420 may also be provided as a window. The shape and material of the transmitting member 1420 may be provided differently depending on the light source to be provided.

What is claimed is:

1. An apparatus of processing a substrate, the apparatus comprising:
a chamber for providing a processing space in which a substrate is processed; and
a transfer unit for loading and unloading the substrate into and from the chamber,
wherein the transfer unit includes:
a hand on which the substrate is placed; and
a position detection assembly for measuring a position of the substrate placed on the hand, and
the position detection assembly includes:
an optical sensor for emitting or receiving the light;
a transmitting member positioned in a path of the light between the substrate placed on the hand and the optical sensor to transmit light; and
a gas supply unit for providing a gas curtain by injecting gas to a first side surface that is the path side of the light from the transmitting member toward the substrate.

2. The apparatus of claim 1, wherein the position detection assembly further includes a cover positioned on the first side surface of the transmitting member and formed with a through-hole through which the light passes, and
the gas curtain is provided in the through-hole.

3. The apparatus of claim 2, wherein the cover is formed with an inflow path through which the gas is supplied through the through-hole and an outflow path through which the gas is discharged through the through-hole.

4. The apparatus of claim 3, wherein the inflow path is provided as a hole inside the cover.

5. The apparatus of claim 4, wherein the outflow path is provided as a groove in an upper wall of the cover, and
the groove is formed on a surface opposite to a surface of the upper wall facing the transmitting member.

6. The apparatus of claim 5, wherein the gas supply unit includes a gas supply line coupled to the inflow path, and
the inflow path is formed in a shape extending in a straight line from the gas supply line.

7. The apparatus of claim 5, wherein the inflow path and the outflow path are provided in a straight line.

8. The apparatus of claim 5, wherein the inflow path and the outflow path are formed parallel to the substrate supported by the hand.

9. The apparatus of claim 5, wherein the optical sensor includes:
a light emitting unit for emitting light; and
a light receiving unit disposed opposite to the light emitting unit on a side opposite to the light emitting unit with respect to the substrate placed on the hand, and
the cover is installed on at least one of the light emitting unit and the light receiving unit, and
the transfer unit includes:
a base;
a support fixed to the base and supporting the light receiving unit; and
a hand for supporting the substrate, and
the hand is installed on the base and is provided to be movable relative to the base in forward and backward directions.

10. The apparatus of claim 9, wherein a plurality of the light emitting units and a plurality of the light receiving units are provided,
one of the light emitting units and one of the light receiving units are provided to detect an edge region of the substrate,
the light emitting units emit light to different regions in the edge region of the substrate, and
the cover and the gas supply unit are respectively installed in the light emitting unit and the light receiving unit.

11. The apparatus of claim 10, wherein the transmitting member is a lens.

12. A transfer unit for transferring a substrate, the transfer unit comprising:
a base;
a hand for supporting a substrate;
a position detection assembly for detecting a position of the substrate; and
a support on which the position detection assembly is installed and which is coupled to the base,
the hand is installed on the base and is provided to be movable relative to the base in forward and backward directions,
the position detection assembly includes:
an optical sensor for emitting light or receiving the light;
a transmitting member positioned in a path of the light between the substrate placed on the hand and the optical sensor to transmit light;
a cover located on the first side surface of the transmitting member; and
a gas supply unit for providing a gas curtain by injecting gas into the through-hole,
the cover is formed with:
a through-hole through which the light passes;
an inflow path through which the gas is supplied through the through-hole; and
an outflow path through which the gas is discharged through the through-hole, and
the gas supply unit injects gas to form a gas curtain in the through-hole.

13. The transfer unit of claim 12, wherein the cover includes the inflow path through which the gas is supplied through the through-hole and the outflow path through which the gas is discharged through the through-hole.

14. The transfer unit of claim 13, wherein the inflow path is provided as a hole inside the cover.

15. The transfer unit of claim 14, wherein the outflow path is provided as a groove in an upper wall of the cover, and
the groove is formed on a surface opposite to a surface of the upper wall facing the transmitting member.

16. The transfer unit of claim 14, wherein the gas supply unit includes a gas supply line coupled to the inflow path,
the inflow path is formed in a shape extending in a straight line from the gas supply line, and
the inflow path and the outflow path are provided in a straight line.

17. The transfer unit of claim 16, wherein the optical sensor includes:
a light emitting unit installed in the base and emitting light;
a light receiving unit installed in the support and disposed to face the light emitting unit on a side opposite to the light emitting unit with respect to the substrate placed on the hand, and
the cover is installed on the light emitting unit and the light receiving unit,
a plurality of the light emitting units and a plurality of the light receiving units are provided,
one of the light emitting units and one of the light receiving units are provided to detect an edge region of the substrate, and
the light emitting units emit light to different regions in the edge region of the substrate.

18. An apparatus of processing a substrate, the apparatus comprising:
a process chamber for providing a processing space in which a substrate is processed; and
a transfer chamber for providing a transfer space for transferring the substrate to a transfer unit,
wherein the transfer chamber includes:
a housing providing the transfer space; and
a fan installed on an upper portion of the housing and forming descending airflow by injecting outside air into the transfer space,
the transfer unit includes:
a base;
a hand for supporting a substrate;
a position detection assembly for detecting a position of the substrate; and
a support on which the position detection assembly is installed and which is coupled to the base,
the hand is installed on the base and is provided to be movable relative to the base in forward and backward directions,
the position detection assembly includes:
an optical sensor for emitting light or receiving the light;
a transmitting member positioned in a path of the light between the substrate placed on the hand and the optical sensor to transmit light;
a cover located on the first side surface of the transmitting member; and
a gas supply unit for providing a gas curtain by injecting gas into the through-hole,
the cover is formed with:
a through-hole through which the light passes;
an inflow path through which the gas is supplied through the through-hole, and which is provided as a hole inside the cover; and
an outflow path which is provided as a groove in an upper wall of the cover and through which the gas is discharged through the through-hole,
the inflow path and the outflow path are formed in a straight line and parallel to the substrate supported by the hand, and
the gas supply unit injects gas to form a gas curtain in the through-hole.

19. The apparatus of claim 18, wherein the optical sensor includes:
a light emitting unit installed in the base and emitting light; and
a light receiving unit installed in the support and disposed to face the light emitting unit on a side opposite to the light emitting unit with respect to the substrate placed on the hand, and
the cover is installed on the light emitting unit and the light receiving unit,
a plurality of the light emitting units and a plurality of the light receiving units are provided,
one of the light emitting units and one of the light receiving units are provided to detect an edge region of the substrate, and
the light emitting units emit light to different regions in the edge region of the substrate.

20. The apparatus of claim 19, wherein a plurality of the light emitting units and a plurality of the light receiving units are provided,
one of the light emitting units and one of the light receiving units are provided to detect an edge region of the substrate, and
the light emitting units emit light to different regions in the edge region of the substrate.
